(19) United States
(12) Patent Application Publication
(10) Pub. No.: US 2006/0097789 A1
(43) Pub. Date: May 11, 2006

(54) Amplifier circuit

(75) Inventor: Michio Irie, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/256,593

(22) Filed: Oct. 21, 2005

(30) Foreign Application Priority Data
Nov. 8, 2004 (JP) 2004-323227

(51) Int. Cl. H03G 3/10

(52) U.S. Cl. 330/284

(57) ABSTRACT

An amplifier circuit includes: an amplifier with a CMOS field effect transistor; and a frequency response control circuit that attenuates low frequency portions of a signal output by the amplifier.

### RELATED APPLICATIONS

This application claims priority to Japanese Patent Application No. 2004-323227 filed Nov. 8, 2004 which is hereby incorporated by reference in its entirety.

### BACKGROUND OF THE INVENTION

1. Technical Field

The present invention relates to an amplifier circuit. More specifically, it relates to an amplifier circuit suitable for application to a method of reducing a 1/f noise that a CMOS-IC generates.

2. Related Art

The progress of CMOS-IC technology in recent years has been partially directed to promoting the manufacture of AN RF circuit in a CMOS-IC, too. However, it has been difficult to ensure a satisfactory signal-to-noise ratio (S/N ratio) when small signals such as radio signals and television signals are treated because a CMOS field effect transistor used in a CMOS circuit generates a noise inversely proportional to a frequency (1/f noise).

WO 02/067415 discloses a method of reducing a 1/f noise of a CMOS-IC, by which low frequency noise components are suppressed by the insertion of a band-pass filter between stages of a multistage amplifier.

However, the method disclosed in WO 02/067415 has a problem in that the method merely reduces noises out of an amplification band by the filter inserted in a narrow-band amplifier and has no effect on noises within the amplification band.

### SUMMARY

Therefore, it is an advantage of the invention to provide an amplifier circuit that incorporates a CMOS field effect transistor to attain an appropriate gain and can reduce a 1/f noise within an amplification band.

An amplifier circuit according to an aspect of the invention includes: an amplifier with a CMOS field effect transistor; and a frequency response control circuit that attenuates low frequency portions of a signal output by the amplifier.

This enables the reduction in 1/f noise even when a CMOS field effect transistor is used to constitute an amplifier. Further, even when small signals such as radio signals and television signals are treated, it becomes possible to ensure a good S/N ratio. Therefore, a CMOS circuit can be used to constitute an RF circuit, which can lower the cost of RF circuits and decrease the power consumption thereof.

According to an aspect of the invention, the amplifier circuit further includes a low noise amplifier connected in a preceding stage of the amplifier, the low noise amplifier including a transistor that is smaller in 1/f noise than the CMOS field effect transistor.

This enables a signal to input to the amplifier after the low noise amplifier is made to attain an appropriate gain. Therefore, even when low frequency portions of a signal output by the amplifier are attenuated, the overall gain of the amplifier circuit can be flattened while a required S/N ratio can be ensured.

According to an aspect of the invention, in the amplifier circuit, a gain of the low noise amplifier is set so as to compensate the frequency response of the frequency response control circuit.

This allows the low noise amplifier to amplify a signal component that is attenuated by the frequency response control circuit, and enables suppression of a 1/f noise. Therefore, it becomes possible to attenuate low frequency portions of a signal output by the amplifier while the overall gain of the amplifier circuit is kept flat. Hence, a CMOS circuit can be used to constitute an RF circuit.

According to an aspect of the invention, the amplifier circuit further includes an automatic gain control (AGC) circuit that adjusts the frequency response of the frequency response control circuit and the gain of the low noise amplifier based on an output level of the amplifier.

This enables adjustments of the attenuation by the frequency response control circuit and the gain of the low noise amplifier according to the input signal level of the amplifier. Therefore, it becomes possible to adjust the gain of the low noise amplifier while the gain of the low noise amplifier is prevented from being saturated.

According to an aspect of the invention, in the amplifier circuit, when the output level of the amplifier is large, an attenuation of the low frequency portions by the frequency response control circuit is made smaller than that in a case where the output level is small, and the gain of the low noise amplifier is made smaller.

This makes it possible to reduce the gain of the low noise amplifier when the input signal level of the amplifier is large. Thus, the gain of the low noise amplifier can be prevented from being saturated while the influence of noise on a signal is suppressed. Therefore, it becomes possible to suppress a 1/f noise while interruptions due to cross-modulation and the like is inhibited. Thus, even when a CMOS circuit is used to constitute an RF circuit, the overall gain of the amplifier circuit can be flattened while a required S/N ratio can be ensured.

Further, when the input signal level of the amplifier is small, it becomes possible to increase the gain of the low noise amplifier. Therefore, 1/f noise can be suppressed while the gain of the low noise amplifier is kept from being saturated. In addition, the gain representing the extent to which the 1/f noise is suppressed can be attained by the low noise amplifier and as such, therefore the overall gain of the amplifier circuit can be flattened.

According to an aspect of the invention, the amplifier circuit further includes: an amplifier with a CMOS field effect transistor; a first variable-capacitance element connected in series in a subsequent stage of the amplifier; a low noise amplifier connected in a preceding stage of the amplifier, the low noise amplifier including a transistor that is smaller in 1/f noise than the CMOS field effect transistor; a second variable-capacitance element connected in parallel in a subsequent stage of the low noise amplifier; an automatic gain control circuit that controls a capacitance of the second variable-capacitance element based on an output level of the amplifier; and an inverting circuit that controls a capacitance of the first variable-capacitance element based on an inverted output of a signal output by the automatic gain control circuit.

This allows the variable-capacitance element to adjust the attenuation of low frequency portions of a signal output by the amplifier in the condition where the gain of the low noise amplifier is made variable. Thus, the attenuation by the frequency response control circuit and the gain of the low noise amplifier can be adjusted according to the input signal level of the amplifier while an enlargement in circuit scale is suppressed. Therefore, an amplifier circuit with a small 1/f noise and good interruption resistance can be realized.

### BRIEF DESCRIPTION OF THE DRAWINGS

The invention will be described with reference to the accompanying drawings, wherein like numbers reference like elements, and wherein:

FIG. 1 is a block diagram showing a schematic configuration of an amplifier circuit according to the first embodiment of the invention;

FIG. 2 is a view showing frequency responses of the amplifier circuit of FIG. 1;

FIG. 3 is a block diagram showing a schematic configuration of an amplifier circuit according to the second embodiment;

FIGS. 4A and 4B are views showing frequency responses of the amplifier circuit of FIG. 3;

FIG. 5 is block diagram showing a schematic configuration of an amplifier circuit according to the third embodiment;

FIGS. 6A and 6B are views of assistance in describing a method of adjusting frequency responses of the amplifier circuit of FIG. 5; and

FIG. 7 is a block diagram showing a schematic configuration of an amplifier circuit according to the fourth embodiment.

### DESCRIPTION OF THE EMBODIMENTS

An amplifier circuit according to the embodiments of the invention will be described below with reference to the drawings.

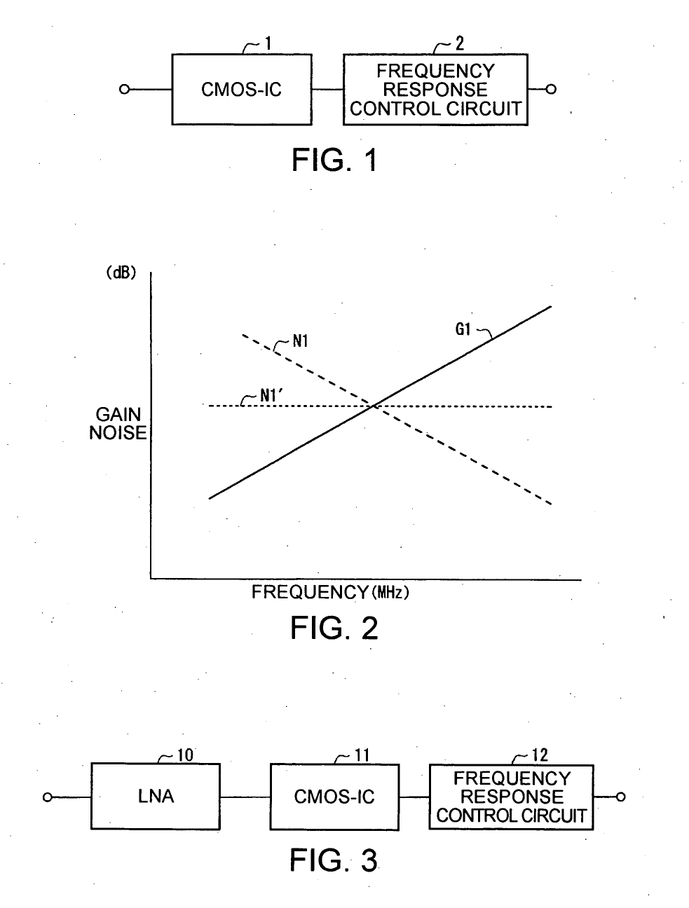

FIG. 1 is a block diagram showing a schematic configuration of an amplifier circuit according to the first embodiment of the invention.

As in FIG. 1, the amplifier circuit has a CMOS-IC 1 provided therein and a frequency response control circuit 2 connected in a subsequent stage of the CMOS-IC 1 to attenuate low frequency portions of a signal amplified by the CMOS-IC 1. Incidentally, the CMOS-IC 1 may include an amplifier with a CMOS field effect transistor. In addition, the frequency response control circuit 2 may include a high-pass filter that attenuates low frequency portions of a signal amplified by the CMOS-IC 1.

A signal that has been input to the CMOS-IC 1 is subjected to, signal processing by the CMOS-IC 1 and input to the frequency response control circuit 2. The frequency response control circuit 2 attenuates low frequency portions of the signal that the CMOS-IC 1 outputs.

This enables the reduction in 1/f noise of the CMOS-IC 1 and makes it possible to ensure a satisfactory S/N ratio even when small signals such as radio signals and television signals are treated. Therefore, a CMOS-IC 1 can be used to constitute an RF circuit, which can lower the cost of RF circuits and decrease power consumption thereof.

FIG. 2 is a view showing frequency responses of the amplifier circuit of FIG. 1.

As in FIG. 2, the lower the frequency is, the larger internal noise N1 the CMOS-IC 1 causes, because the CMOS-IC 1 includes a CMOS field effect transistor and generates a 1/f noise. However, the frequency response control circuit 2 attenuates low frequency portions of a signal amplified in the CMOS-IC 1, whereby an overall gain G1 by the CMOS-IC 1 and frequency response control circuit 2 is set so that the lower the frequency is, the lower the gain is. As a result, the 1/f noise that the CMOS-IC 1 generates can be suppressed, and therefore the noise N1′ caused by the amplifier circuit that includes the CMOS-IC 1 can be flattened.

FIG. 3 is a block diagram showing a schematic configuration of an amplifier circuit according to the second embodiment of the invention.

As in FIG. 3, the amplifier circuit has a CMOS-IC 11 provided therein and a frequency response control circuit 12 connected in a subsequent stage of the CMOS-IC 11 to attenuate low frequency portions of a signal amplified by the CMOS-IC 11. Further, in a preceding stage of the CMOS-IC 11 is connected a low noise amplifier 10 that is smaller in 1/f noise than the CMOS-IC 11. Incidentally, the low noise amplifier 10 can attain e.g. a gain approximately as large as 10 to 15 dB, and the CMOS-IC 11 can achieve e.g. a gain approximately as large as 40 to 50 dB

As the low noise amplifier 10 here, a low noise element such as a bipolar transistor may be used. Also, a transistor with a high electron mobility such as HEMT may be used. The gain of the low noise amplifier 10 can be set so as to compensate the frequency response of the frequency response control circuit 12.

A signal to be input to the CMOS-IC 11 is amplified in its low frequency portions by the low noise amplifier 10 and then entered into the CMOS-IC 11. The amplification of a signal to be input to the CMOS-IC 11 by the low noise amplifier 10 enables the suppression of noise components that would be superimposed on the signal to be input to the CMOS-IC 11. When a signal amplified by the low noise amplifier 10 is input to the CMOS-IC 11, the signal undergoes signal processing by the CMOS-IC 11, and then input to the frequency response control circuit 12. The frequency response control circuit 12 attenuates low frequency portions of the signal that the CMOS-IC 11 has-output.

Thus, the gain that will be lost due to the attenuation by the frequency response control circuit 12 can be attained in the low noise amplifier 10 before a signal is input to the CMOS-IC 11. Therefore, even when low frequency portions of a signal output from the CMOS-IC 11 are attenuated, the overall gain of the amplifier circuit can be flattened while a required S/N ratio is ensured.

In addition, the series connection of the low noise amplifier 10 in the preceding stage of the CMOS-IC 11 allows the CMOS-IC 11 to complement the gain achieved by only the low noise amplifier 10, which would be insufficient. Therefore, it becomes possible to attain a required gain while an increase in the cost can be suppressed.

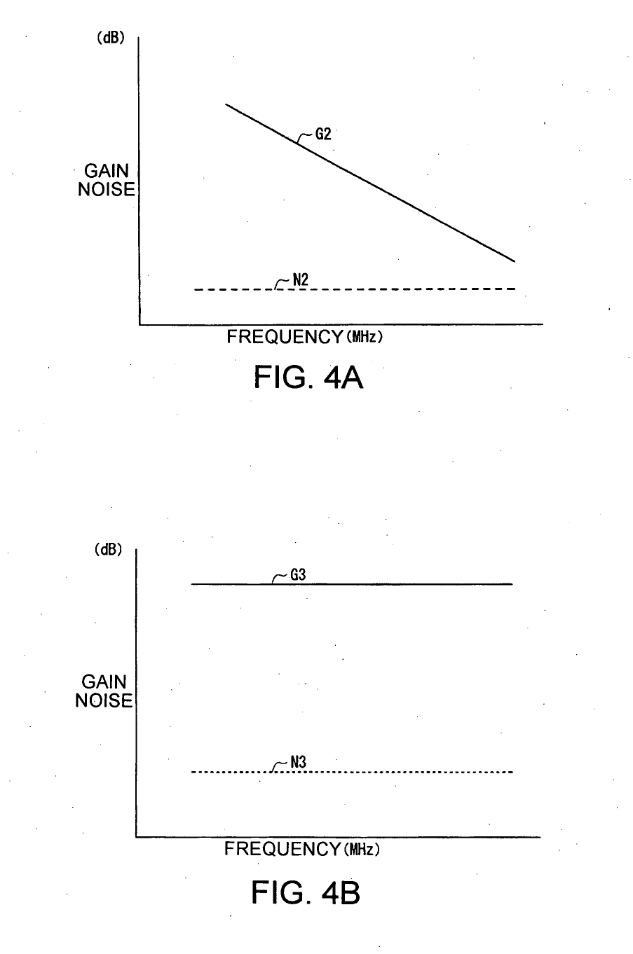

FIGS. 4A, 4B are views showing frequency responses of the amplifier circuit of FIG. 3. Of the drawings, FIG. 4A shows frequency responses of gain and noise of the low noise amplifier 10, and FIG. 4B shows frequency responses of gain and noise of the entire amplifier circuit of FIG. 3.

As in FIGS. 4A, 4B, even when low frequency portions of a signal are output by the low noise amplifier 10 with a gain G2, a noise N2 output from the low noise amplifier 10 can be reduced because 1/f noise of the low noise amplifier 10 is smaller than that of the CMOS-IC 11. Therefore, the gain that represents the attenuation by the frequency response control circuit 12 can be attained by the low noise amplifier 10 while 1/f noise is suppressed. As a result, using the frequency response control circuit 12 to attenuate low frequency portions of a signal subjected to the amplification, by the CMOS-IC 11 can flatten the overall gain G3 of the amplifier circuit and therefore reduce the noise N3 of the amplifier circuit that includes the CMOS-IC 11.

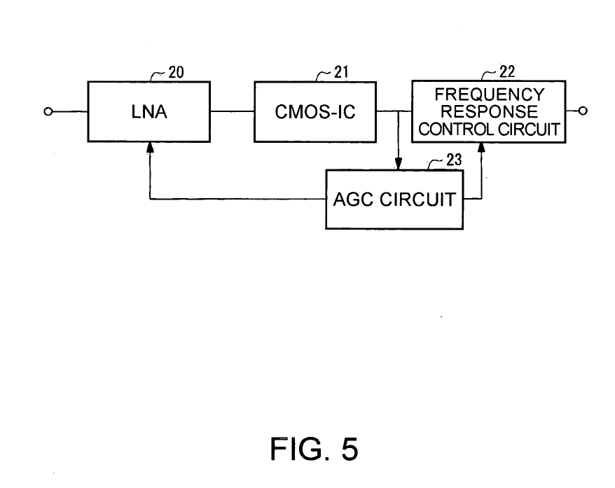

FIG. 5 is a block diagram showing a schematic configuration of an amplifier circuit according to the third embodiment of the invention.

As in FIG. 5, the amplifier circuit has a CMOS-IC 21 provided therein, and a frequency response control circuit 22 connected in the subsequent stage of the CMOS-IC-21 to attenuate low frequency portions of a signal amplified by the CMOS-IC 21. In the preceding stage of the CMOS-IC 21, a low noise amplifier 20 that is smaller in 1/f noise than the CMOS-IC 21 is connected. The amplifier circuit is further provided with an automatic gain control circuit 23 that adjusts the frequency response of the frequency response control circuit 22 and the gain of the low noise amplifier 20 based on an output level of the CMOS-IC 21.

A signal output by the CMOS-IC 21 is input to the automatic gain control circuit 23, and the output level of the CMOS-IC 21 is judged by the automatic gain control circuit 23. Then, the automatic gain control circuit 23 adjusts the frequency response of the frequency response control circuit 22 and the gain of the low noise amplifier 20 based on the output level of the CMOS-IC 21. Here, the automatic gain control circuit 23 can adjust frequency responses of the frequency response control circuit 22 so that low frequency portions of a signal amplified by the CMOS-IC 21 are attenuated, and adjust the gain of the low noise amplifier 20 so that the low noise amplifier 20 complements the gain representing the attenuation by the frequency response control circuit 22.

A signal to be input to the CMOS-IC 21 is amplified in its low frequency portions by the low noise amplifier 20, and then entered into the CMOS-IC 21. When the signal amplified by the low noise amplifier 20 is input to the CMOS-IC 21, subjected to signal processing by the CMOS-IC 21, and then input to the frequency response control circuit 22. The frequency response control circuit 22 attenuates low frequency portions of a signal output by the CMOS-IC 21.

This allows the gain of the low noise amplifier 20 to be made smaller when the input signal level of the CMOS-IC 21 is large. Thus, the gain of the low noise amplifier 20 can be prevented from being saturated while the influence of noise on a signal is suppressed. Hence, it becomes possible to suppress a 1/f noise while the occurrence of interruption due to interference, modulation, and the like is inhibited. Further, even when the CMOS-IC 21 is used to constitute, the RF circuit, a required S/N ratio can be ensured and the overall gain of the amplifier circuit can be flattened.

When the input signal level of the CMOS-IC 21 is small, it becomes possible to increase the gain of the low noise amplifier 20. Thus, the 1/f noise can be suppressed while the gain of the low noise amplifier 20 is kept from being saturated. The gain representing the extent to which the 1/f noise is also suppressed can be attained by the low noise amplifier 20. The overall gain of the amplifier circuit can be thus flattened.

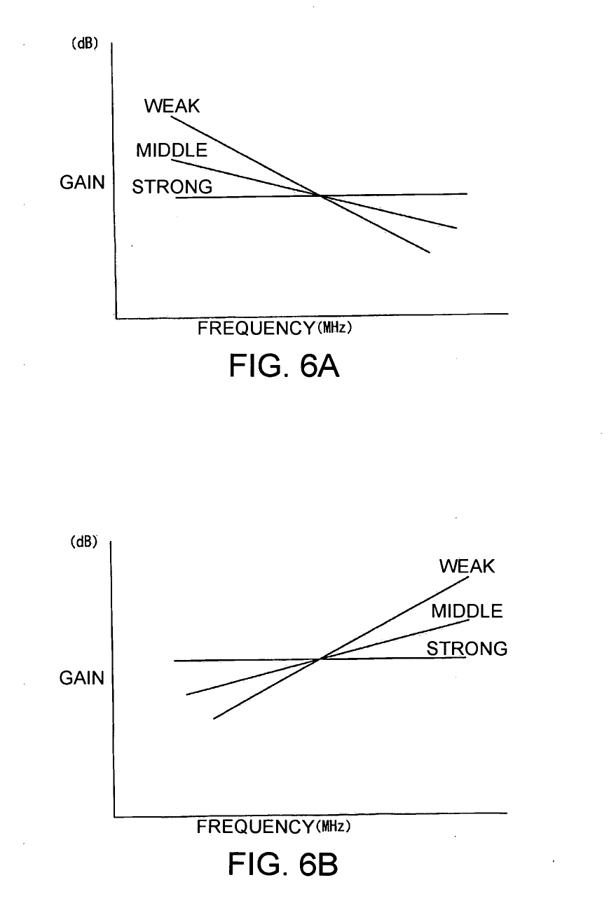

FIGS. 6A and 6B are views of assistance in describing a method of adjusting frequency responses of the amplifier circuit of FIG. 5. Of the drawings, FIG. 6A shows frequency responses of the low noise amplifier 20, and FIG. 6B shows frequency responses of the frequency response control circuit 22.

As in FIGS. 6A and 6B, under a weak electric field, variations in frequency responses of the low noise amplifier 20 and frequency response control circuit 22 are made larger. Under such a weak electric field, the saturation of the low noise amplifier 20 can be prevented and the interruption due to interference, modulation, and the like can be made harder to arise even when the gain of the low noise amplifier 20 is increased. Also, while the influence of a noise becomes larger when the input signal level to the CMOS-IC 21 is smaller, the gain of the low noise amplifier 20 can be attained so as to overcome the noise.

In contrast, under a strong electric field, frequency responses of the low noise amplifier 20 and the frequency response control circuit 22 are made flat. This is because when the low noise amplifier 20 has a frequency response under a strong electric field, the gain of the low noise amplifier 20 is saturated in a low frequency portion, causing the interruption due to interference, modulation, and the like. In this case, even when the frequency response of the low noise amplifier 20 is made flat, the input signal level to the CMOS-IC 21 is large and as such, the influence of a noise can be made smaller and a required S/N ratio can be ensured.

The frequency response of the frequency response control circuit 22 is changed according to the strength of the electric field so that it changes reversely with respect to the frequency response of the low noise amplifier 20. Under a medium electric field, the frequency responses of the low noise amplifier 20 and frequency response control circuit 22 can be set so as to be in a medium condition between weak and strong electric fields.

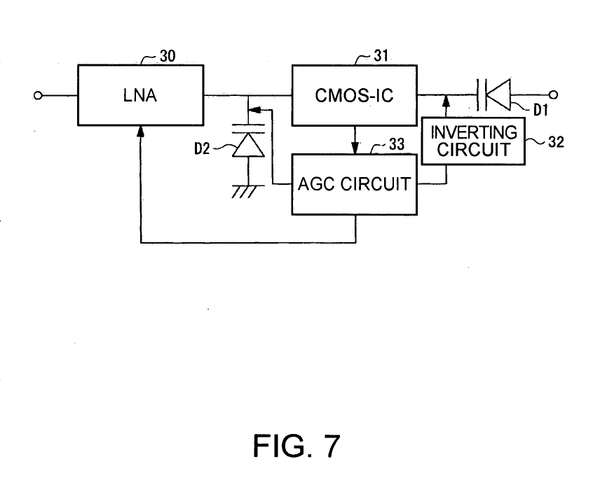

FIG. 7 is a block diagram showing a schematic configuration of an amplifier circuit according to the fourth embodiment of the invention.

As in FIG. 7, the amplifier circuit has a CMOS-IC 31 provided therein, and a variable-capacitance element D1 connected in series in a subsequent stage of the CMOS-IC 31. Further, in a preceding stage of the CMOS-IC 31 is connected a low noise amplifier 30, which causes a 1/f noise smaller than that generated by the CMOS-IC 31. In a subsequent stage of the low noise amplifier 30, a variable-capacitance element D2 is connected in parallel. The amplifier circuit is provided with an automatic gain control circuit 33 that controls the capacitance of the variable-capacitance element D2 based on the output level of the CMOS-IC 31, and an inverting circuit 32 that controls the capacitance of the variable-capacitance element D1 based on the inverted output of a signal output by the automatic gain control circuit 33. Incidentally, the variable-capacitance elements D1 and D2 may be, for example, a varicap diode.

A signal output by the CMOS-IC 31 is input to the automatic gain control circuit 33, by which the output level of the CMOS-IC 31 is judged. Then, the automatic gain control circuit 33 outputs an AGC voltage corresponding to the output level of the CMOS-IC 31 to the variable-capacitance element D2. The AGC voltage output by the automatic gain control circuit 33 is inverted in the inverting circuit 32 and then output to the variable-capacitance element D1.

A signal to be input to the CMOS-IC 31 is amplified in its low frequency portions by the low noise amplifier 30 and then entered into the CMOS-IC 31. When a signal amplified by the low noise amplifier 30 is input to the CMOS-IC 31, the signal is subjected to signal processing by the CMOS-IC 31, and entered into the frequency response control circuit 32. Low frequency portions of a signal output by the CMOS-IC 31 are thus attenuated.

When the output level of the CMOS-IC 31 is made smaller, an AGC voltage output by the automatic gain control circuit 33 is decreased to reduce the capacitance of the variable-capacitance element D1 and increase the capacitance of the variable-capacitance element D2. Then, the gain is attained by the low noise amplifier 20 so as to overcome a noise under a weak electric field. After that, the variation in frequency response is increased by increasing the capacitance of the variable-capacitance element D2. In other words, the gain in a low frequency portion is raised and the gain in a high frequency portion is lowered. As a result, the influence of a noise can be made smaller even when the input signal level to the CMOS-IC 21 is small. Further, under a weak electric field, even when the gain of the low noise amplifier 20 is increased, the saturation of the low noise amplifier 20 can be prevented, and therefore the interruption due to interference, modulation, and the like can be made harder to arise.

In addition, decreasing the capacitance of the variable-capacitance element D1 can increase the attenuation of low frequency portions by the variable-capacitance element D1. Therefore, it is possible to suppress a 1/f noise while the flatness of the overall gain of the amplifier circuit is ensured.

In contrast, when the output level of the CMOS-IC 31 is made larger, an AGC voltage output by the automatic gain control circuit 33 is increased, increasing the capacitance of the variable-capacitance element D1 and decreasing the capacitance of the variable-capacitance element D2. Therefore, under a strong electric field, the frequency responses of the low noise amplifier 30 and frequency response control circuit 32 can be made flat, whereby the gain of the low noise amplifier 30 in a low frequency portion can be prevented from being saturated and the occurrence of interruption due to interference, modulation, and the like is inhibited. In this case, even when the frequency response of the low noise amplifier 30 is made flat, the input signal level to the CMOS-IC 31 is large and as such, the influence of a noise can be made smaller to ensure a required S/N ratio.

What is claimed is:

1. An amplifier circuit, comprising:
an amplifier with a CMOS field effect transistor; and
a frequency response control circuit that attenuates low frequency portions of a signal output by the amplifier.

2. The amplifier circuit of claim 1, further comprising a low noise amplifier connected in a preceding stage of the amplifier, the low noise amplifier including a transistor that is smaller in 1/f noise than the CMOS field effect transistor.

3. The amplifier circuit of claim 2, wherein a gain of the low noise amplifier is set so as to compensate a frequency response of the frequency response control circuit.

4. The amplifier circuit of claim 3, further comprising an automatic gain control circuit that adjusts the frequency response of the frequency response control circuit and the gain of the low noise amplifier based on an output level of the amplifier.

5. The amplifier circuit of claim 4, wherein when the output level of the amplifier is large, an attenuation of the low frequency portions by the frequency response control circuit is made smaller than in a case where the output level is small, and the gain of the low noise amplifier is made smaller.

6. The amplifier circuit of claim 1, further comprising:
an amplifier with a CMOS field effect transistor;
a first variable-capacitance element connected in series in a subsequent stage of the amplifier;
a low noise amplifier connected in a preceding stage of the amplifier, the low noise amplifier including a transistor that is smaller in 1/f noise than the CMOS field effect transistor;
a second variable-capacitance element connected in parallel in a subsequent stage of the low noise amplifier;
an automatic gain control circuit that controls a capacitance of the second variable-capacitance element based on an output level of the amplifier; and
an inverting circuit that controls a capacitance of the first variable-capacitance element based on an inverted output of a signal output by the automatic gain control circuit.
